(19) United States
(12) Patent Application Publication
(10) Pub. No.: US 2024/0155872 A1
(43) Pub. Date: May 9, 2024

(54) Display Substrate and Preparation Method Therefor, and Display Device

(71) Applicants: Chengdu BOE Optoelectronics Technology Co., Ltd., Chengdu, Sichuan (CN); BOE Technology Group Co., Ltd., Beijing (CN)

(72) Inventors: Yu Wang, Beijing (CN); Cong Fan, Beijing (CN); Xiangdan Dong, Beijing (CN); Donghui Tian, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/281,247

(22) PCT Filed: Sep. 22, 2022
(86) PCT No.: PCT/CN2022/120542

§ 371 Date: Sep. 8, 2023

(30) Foreign Application Priority Data
Nov. 25, 2021 (CN) 202111414039.4

(51) Int. Cl. H10K 59/121; H01L 29/417; H01L 29/786; H10K 59/12; H10K 71/60

(52) U.S. Cl. CPC H10K 59/1213; H01L 29/41733; H01L 29/78645; H10K 59/1201; H10K 59/1216; H10K 71/60

(57) ABSTRACT

A display substrate and a preparation method therefor, and a display device. The display substrate includes a display area, a blocking area, an opening area, and a base substrate. The blocking area includes at least one blocking wall at least partially surrounding the opening area. Each blocking wall includes a first metal layer structure and a first stack structure, and at least one side surface of the first metal layer structure surrounding the opening area (301) includes a first notch. The display area includes a plurality of sub-pixels, each sub-pixel includes a pixel driving circuit and a light-emitting device, the pixel driving circuit includes a thin-film transistor and a connector electrode, and the thin-film transistor includes a first source/drain electrode and a second source/drain electrode. The light-emitting device includes a first electrode a second electrode, and a light-emitting material layer between the first electrode and the second electrode.

The application claims priority to the Chinese patent application No. 202111414039.4, filed on Nov. 25, 2021, the entire disclosure of which is incorporated herein by reference as part of the present application.

### TECHNICAL FIELD

Embodiments of the present disclosure relate to a display substrate and a method for preparing the same, and a display device.

### BACKGROUND

At present, the display screen of display devices is developing towards large screen and full screen. Generally, a display device (such as a mobile phone, a tablet computer, etc.) has a camera device (or an imaging device), and the camera device is usually arranged on a side outside the display area of a display screen. However, because the installation of the camera device needs a certain position, it is not beneficial to realizing the full screen and narrow bezel design of the display screen. For example, the camera can be combined with the display area of the display screen, and a position can be reserved for the camera in the display area to maximize the display area of the display screen.

### SUMMARY

At least one embodiment of the present disclosure provides a display substrate, having a display area, a barrier region, and an opening region, and comprising a base substrate, the display area and the barrier region surround the opening region, and the barrier region is between the display area and the opening region, the barrier region comprises at least one barrier wall at least partially surrounding the opening region, and each of the at least one barrier wall comprises a first metal layer structure and a first stack structure, the first metal layer structure is on a side of the first stack structure away from the base substrate, and at least a side surface, surrounding the opening region, of the first metal layer structure has a first notch; the display area comprises a plurality of sub-pixels, each of the plurality of sub-pixels comprises a pixel driver circuit and a light-emitting device, the pixel driver circuit comprises a thin film transistor and a connection electrode, and the thin film transistor comprises a first source-drain electrode and a second source-drain electrode, and the light-emitting device comprises a first electrode, a second electrode, and a light-emitting material layer between the first electrode and the second electrode, and the connection electrode is configured to electrically connect the first electrode and the first source-drain electrode; and the first metal layer structure is in a same layer as the connection electrode.

For example, in the display substrate provided by at least an embodiment of the present disclosure, the first metal layer structure comprises a first metal sub-layer and a second metal sub-layer on a side of the first metal sub-layer away from the base substrate, and the first metal sub-layer is retracted inward relative to the second metal sub-layer in a direction parallel to a board surface of the base substrate to form the first notch; or, the first metal layer structure comprises a first metal sub-layer, a second metal sub-layer on a side of the first metal sub-layer away from the base substrate, and a third metal sub-layer on a side of the first metal sub-layer near the base substrate, and the first metal sub-layer is retracted inward relative to the second metal sub-layer and the third metal sub-layer in the direction parallel to the board surface of the base substrate to form the first notch.

For example, in the display substrate provided by at least an embodiment of the present disclosure, the display area further comprises a first planarization layer on a side of the first source-drain electrode and the second source-drain electrode away from the base substrate, the first planarization layer has a first via hole, and the connection electrode is on a side of the first planarization layer away from the base substrate and is electrically connected with the first source-drain electrode through the first via hole, the first stack structure comprises a first insulation sub-layer on the base substrate, and the first insulation sub-layer and the first planarization layer are in a same layer.

For example, in the display substrate provided by at least an embodiment of the present disclosure, the at least one barrier wall comprises a plurality of barrier walls; the first metal layers of the plurality of barrier walls are in a same layer and spaced apart from each other, and the first stack structures of the plurality of barrier walls are in a same layer and spaced apart from each other; or, the first metal layers of the plurality of barrier walls are in a same layer and spaced apart from each other, and the first stack structures of the plurality of barrier walls are in the same layer and constitute an integral structure.

For example, in the display substrate provided by at least an embodiment of the present disclosure, the integral structure has a barrier groove between the first metal layer structures of adjacent ones of the plurality of barrier walls.

For example, in the display substrate provided by at least an embodiment of the present disclosure, the display area further comprises a first passivation layer on a side of the first planarization layer away from the base substrate, the first passivation layer has a second via hole communicated with the first via hole, the connection electrode is on a side of the first passivation layer away from the base substrate, and is electrically connected with the first source-drain electrode through the first via hole and the second via hole, the first stack structure further comprises a second insulation sub-layer arranged on a side of the first insulation sub-layer away from the base substrate, and the second insulation sub-layer and the first passivation layer are in a same layer.

For example, in the display substrate provided by at least an embodiment of the present disclosure, the first insulation sub-layer has a groove between the first metal layer structures of adjacent ones of the plurality of barrier walls, and the second insulation sub-layer is formed on a side of the first insulation sub-layer away from the base substrate with an equal thickness to form the barrier groove at the position of the groove.

For example, in the display substrate provided by at least an embodiment of the present disclosure, the display area further comprises a second passivation layer arranged on a side of the first source-drain electrode and the second source-drain electrode away from the base substrate, the second passivation layer has a third via hole, and the connection electrode is on a side of the second passivation layer away from the base substrate and is electrically connected with the first source-drain electrode through the third via hole, the first stack structure comprises a third insulation sub-layer on the base substrate, and the third insulation sub-layer and the second passivation layer are arranged in the same layer.

For example, in the display substrate provided by at least an embodiment of the present disclosure, the at least one barrier wall comprises a plurality of barrier walls; the first metal layers of the plurality of barrier walls are in a same layer and spaced apart from each other, and the first stack structures of the plurality of barrier walls are in a same layer and spaced apart from each other; or, the first metal layers of the plurality of barrier walls are in a same layer and spaced apart from each other, and the first stack structures of the plurality of barrier walls are in the same layer and constitute an integral structure.

For example, in the display substrate provided by at least an embodiment of the present disclosure, the third insulation sub-layer in the integral structure has a barrier groove between the first metal layer structures of adjacent ones of the plurality of barrier walls.

For example, in the display substrate provided by at least an embodiment of the present disclosure, the first stack structure further comprises a first metal layer, the first metal layer is on a side of the first insulation sub-layer near the base substrate, and the first metal layer is in a same layer as the first source-drain electrode and the second source-drain electrode.

For example, in the display substrate provided by at least an embodiment of the present disclosure, the pixel driver circuit further comprises a storage capacitor, the thin film transistor further comprises a first gate electrode, and the first gate electrode is on a side of the first source-drain electrode and the second source-drain electrode near the base substrate, the storage capacitor comprises a first capacitor plate and a second capacitor plate, the first capacitor plate is in a same layer as the first gate electrode, and the second capacitor plate is on a side of the first capacitor plate away from the base substrate, the first stack structure further comprises a second metal layer and a third metal layer, the second metal layer is on a side of the third metal layer away from the base substrate, the second metal layer is in a same layer as the second capacitor plate, and the third metal layer is in the same layer as the first capacitor plate.

For example, in the display substrate provided by at least an embodiment of the present disclosure, the display area further comprises a gate insulation layer between the first gate electrode and the second capacitor plate, and the gate insulation layer further extends into the barrier region and is between the second metal layer and the third metal layer.

For example, in the display substrate provided by at least an embodiment of the present disclosure, the display area further comprises an interlayer insulation layer on a side of the second capacitor plate away from the base substrate, and the interlayer insulation layer further extends into the barrier region and is on a side of the second metal layer away from the base substrate.

For example, in the display substrate provided by at least an embodiment of the present disclosure, the thin film transistor further comprises a second gate electrode, and the second gate electrode is on a side of the interlayer insulation layer away from the base substrate, the first stack structure further comprises a fourth metal layer, and the fourth metal layer is in a same layer as the second gate electrode.

For example, the display substrate provided by at least an embodiment of the present disclosure further comprises: a circuit region which is between the display area and the barrier region and at least partially surrounds the display area, the circuit region comprises a plurality of conductive layers and a plurality of insulation layers between adjacent ones of the plurality of conductive layers.

At least one embodiment of the present disclosure also provides a display device, comprising the display substrate of the embodiments of the present disclosure.

At least one embodiment of the present disclosure also provides a method for preparing a display substrate, comprising: forming a display area, a barrier region, and an opening region, the display area and the barrier region surround the opening region, and the barrier region is between the display area and the opening region; forming the barrier region comprises: forming at least one barrier wall at least partially surrounding the opening region, each of the at least one barrier walls comprises a first metal layer structure and a first stack structure, and the first metal layer structure is formed on a side of the first stack structure away from the base substrate, and at least a side surface, surrounding the opening region, of the first metal layer structure has a first notch; forming the display area comprises: forming a plurality of sub-pixels, each of the plurality of sub-pixels comprises a pixel driver circuit and a light-emitting device, the pixel driver circuit comprises a thin film transistor and a connection electrode, and the thin film transistor comprises a first source-drain electrode and a second source-drain electrode, and the light-emitting device comprises a first electrode, a second electrode and a light-emitting material layer between the first electrode and the second electrode, and the connection electrode is formed to electrically connect the first electrode and the first source-drain electrode; and the first metal layer structure and the connection electrode are formed in a same layer.

For example, in the preparation method provided by at least an embodiment of the present disclosure, the first metal layer structure comprises a first metal sub-layer and a second metal sub-layer on a side of the first metal sub-layer away from the base substrate, and the first metal sub-layer is retracted inward relative to the second metal sub-layer in a direction parallel to a board surface of the base substrate to form the first notch; or, the first metal layer structure comprises a first metal sub-layer, a second metal sub-layer on a side of the first metal sub-layer away from the base substrate, and a third metal sub-layer on a side of the first metal sub-layer near the base substrate, and the first metal sub-layer is retracted inward relative to the second metal sub-layer and the third metal sub-layer in the direction parallel to the board surface of the base substrate to form the first notch; forming the display area further comprises: forming a first planarization layer on a side of the first source-drain electrode and the second source-drain electrode away from the base substrate, the first planarization layer has a first via hole, and the connection electrode is formed on a side of the first planarization layer away from the base substrate and is electrically connected with the first source-drain electrode through the first via hole, the first stack structure comprises a first insulation sub-layer formed on the base substrate, and the first insulation sub-layer and the first planarization layer are formed in a same layer.

For example, in the preparation method provided by at least an embodiment of the present disclosure, the first metal layer structure comprises a first metal sub-layer and a second metal sub-layer formed on a side of the first metal sub-layer away from the base substrate, and the first metal sub-layer is formed to be retracted inward relative to the second metal sub-layer in a direction parallel to a board surface of the base substrate to form the first notch; or, the first metal layer structure comprises a first metal sub-layer, a second metal sub-layer formed on a side of the first metal sub-layer away from the base substrate, and a third metal sub-layer formed on a side of the first metal sub-layer near the base substrate, and the first metal sub-layer is formed to be retracted inward relative to the second metal sub-layer and the third metal sub-layer in the direction parallel to the board surface of the base substrate to form the first notch; forming the display area further comprises: forming a second passivation layer on a side of the first source-drain electrode and the second source-drain electrode away from the base substrate, the second passivation layer has a third via hole, and the connection electrode is formed on a side of the second passivation layer away from the base substrate and is electrically connected with the first source-drain electrode through the third via hole, the first stack structure comprises a third insulation sub-layer formed on the base substrate, and the third insulation sub-layer is formed in a same layer as the second passivation layer.

For example, in the preparation method provided by at least an embodiment of the present disclosure, forming the first metal layer structure and the connection electrode comprises: forming a connection electrode material layer, and pattern the connection electrode material layer to form the connection electrode and a first metal layer initial structure; forming a second planarization layer on a side of the connection electrode and the first metal layer initial structure away from the base substrate, the second planarization layer comprises a third via hole exposing the connection electrode and an opening exposing the first metal layer initial structure; forming a first electrode material layer on a side of the second planarization layer away from the base substrate, etching the first electrode material layer and the initial structure of the first electrode material layer with a same etching solution to form the first electrode and the first notch, and the first electrode is electrically connected with the connection electrode through the third via hole.

For example, the preparation method provided by at least an embodiment of the present disclosure further comprises: forming a circuit region which is between the display area and the barrier region and at least partially surrounding the display area, the circuit region comprises a plurality of conductive layers, and a plurality of insulation layers between adjacent ones of the plurality of conductive layers, after the connection electrode and the first metal layer initial structure are formed, the plurality of conductive layers and the plurality of insulation layers between the adjacent ones of the plurality of conductive layers are formed, and then the first electrode material layer and the first metal layer initial structure are etched by a same etching solution.

### BRIEF DESCRIPTION OF DRAWINGS

In order to clearly illustrate the technical solution of the embodiments of the disclosure, the drawings of the embodiments will be briefly described in the following; it is apparent that the described drawings are only related to some embodiments of the disclosure and thus are not limitative of the disclosure.

FIG. 1A is a schematic plan view of a display substrate;

FIG. 1B is a schematic cross-sectional view of the display substrate in FIG. 1A taken along the line A-A;

FIG. 2 is a schematic plan view of a display substrate provided by at least one embodiment of the present disclosure;

FIG. 3 is a schematic cross-sectional view of the display substrate in FIG. 2 taken along the line B-B;

FIG. 4 is a schematic cross-sectional view of the display substrate in FIG. 2 taken along the line C-C;

FIG. 5A is a schematic cross-sectional view of a barrier wall in a display substrate provided by at least one embodiment of the present disclosure;

FIG. 5B is another schematic cross-sectional view of a barrier wall in a display substrate provided by at least one embodiment of the present disclosure;

FIG. 5C is a schematic cross-sectional view of a connection electrode in a display substrate provided by at least one embodiment of the present disclosure;

FIG. 5D is another schematic cross-sectional view of a connection electrode in a display substrate provided by at least one embodiment of the present disclosure;

FIG. 5E is a schematic cross-sectional view of the light-emitting material layer disconnected by the barrier wall in a display substrate provided by at least one embodiment of the present disclosure;

FIG. 6A is another schematic cross-sectional view of the display substrate in FIG. 2 taken along the line B-B;

FIG. 6B is further another schematic cross-sectional view of the display substrate in FIG. 2 taken along the line B-B;

FIG. 6C is yet another schematic cross-sectional view of the display substrate in FIG. 2 taken along the line B-B;

FIG. 6D is yet another schematic cross-sectional view of the display substrate in FIG. 2 taken along the line B-B;

FIG. 7A is another schematic cross-sectional view of the display substrate in FIG. 2 taken along the line C-C;

FIG. 7B is yet another schematic cross-sectional view of the display substrate in FIG. 2 taken along the line C-C;

FIG. 8 is another schematic cross-sectional view of the display substrate in FIG. 2 taken along the line B-B; and

FIGS. 9A-13B are schematic cross-sectional views of a display substrate provided by at least one embodiment of the present disclosure in a preparation process.

### DETAILED DESCRIPTION

To make the objective, technical solutions and advantages clearer, the technical solutions of the embodiments will be described in a clearly and fully understandable way in connection with the related drawings. The described embodiments are just a part but not all of the embodiments of the present disclosure. Based on the described embodiments herein, a person of ordinary skill in the art can obtain, without any creative work, other embodiment(s) which should be within the scope of the present disclosure.

Unless otherwise defined, all the technical and scientific terms used herein have the same meanings as commonly understood by one of ordinary skill in the art to which the present disclosure belongs. The terms, such as “first,” “second,” or the like, which are used in the present disclosure, are not intended to represent any sequence, amount or importance, but for distinguishing various components. Also, the terms, such as “comprise/comprising,” “include/including,” or the like are intended to specify that the elements or the objects before these terms encompass the elements or the objects and equivalents thereof listed after these terms, while not preclude other elements or objects. The terms, such as “connect/connecting/connected,” or the like, are not limited to a physical connection or mechanical connection, but may include an electrical connection/coupling, directly or indirectly. The terms, “on,” “under,” “left,” “right” or the like are only used to represent relative position relationship, and when the absolute position of the object which is described is changed, the relative position relationship may be changed accordingly.

In order to maximize the display area of the display device, the camera (imaging device) of the display device can be integrated with the display area, and the camera can be arranged in the display area.

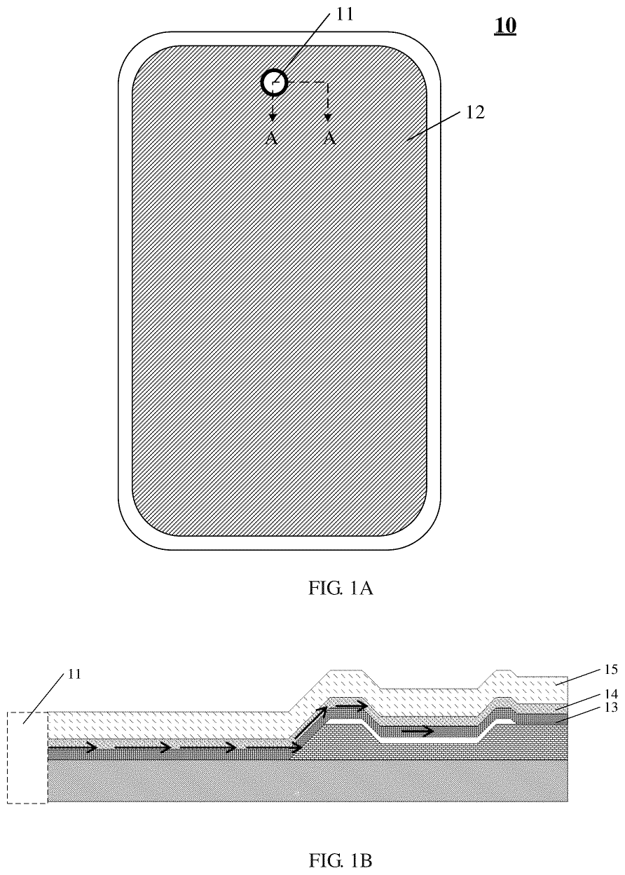

For example, FIG. 1A shows a schematic plan view of a display substrate for a display device, and FIG. 1B is a schematic cross-sectional view of the display substrate in FIG. 1A taken along the line A-A. As shown in FIG. 1A, the display substrate 10 includes a display area 12, the display area 12 includes a pixel array and has an opening 11 in the pixel array. The opening 11 is reserved for a camera (not shown), and the camera can be arranged on the back side of the display substrate 10 opposite to the display side, so that the camera can acquire images through the opening 11. In this way, the camera is integrated with the display area 12 of the display substrate 10.

The display area 12 has a light-emitting devices for display, for example, the light-emitting devices are organic light-emitting diodes, and the organic material layer 13 and electrode layer 14 of a plurality of light-emitting devices in all or part of the display area 12 are usually formed in the whole region of the display area 12, so when the encapsulation layer 15 is used for encapsulating the display substrate, it is often difficult to encapsulate the region near the opening 11, or even if it is encapsulated, it is difficult to ensure the encapsulation effect of this region. In this case, as shown in FIG. 1B, impurities, such as water and oxygen, can enter the display area 12 from the opening 11 along the organic functional layer 13 and the electrode layer 14 that are formed in the whole region of the display area, polluting the functional materials in the display area 12, causing the performance degradation of these functional materials and further affecting the display effect of the display area 12.

At least one embodiment of the present disclosure provides a display substrate and a method for preparing the same, and a display device, the display substrate has a display area, a barrier region and an opening region, and comprises a base substrate, the display area and the barrier region surround the opening region, and the barrier region is between the display area and the opening region, the barrier region comprises at least one barrier wall at least partially surrounding the opening region, and each of the at least one barrier wall comprises a first metal layer structure and a first stack structure, the first metal layer structure is on a side of the first stack structure away from the base substrate, and at least a side surface, surrounding the opening region, of the first metal layer structure has a first notch; the display area comprises a plurality of sub-pixels, each of the plurality of sub-pixels comprises a pixel driver circuit and a light-emitting device, the pixel driver circuit comprises a thin film transistor and a connection electrode, and the thin film transistor comprises a first source-drain electrode and a second source-drain electrode, and the light-emitting device comprises a first electrode, a second electrode, and a light-emitting material layer between the first electrode and the second electrode, and the connection electrode is configured to electrically connect the first electrode and the first source-drain electrode; and the first metal layer structure is in a same layer as the connection electrode.

In the display substrate, the barrier wall can be used to disconnect the functional layers, such as the light-emitting material layer, so as to effectively prevent impurities, such as water and oxygen, from entering the display area of the display substrate along the functional layers, such as the light-emitting material layer, from the opening region, thereby improving the reliability of the display substrate; in addition, the first metal layer structure of the barrier wall is arranged in the same layer as the connection electrode, so that it can be formed by a same patterning process in the preparation process of the display substrate, which simplifies the preparation process of the display substrate; on the other hand, because the barrier wall includes the first stack structure and the first metal layer structure arranged on the first stack structure, the height of the first metal layer structure relative to the base substrate is relatively high, and when the first metal layer structure of the barrier wall is formed by a patterning process, the problems that it is difficult to etch and form the first notch of the first metal layer structure due to too thick photoresist can be avoided.

The display substrate, the method for preparing the same and the display device of the present disclosure are described through several specific embodiments in the following.

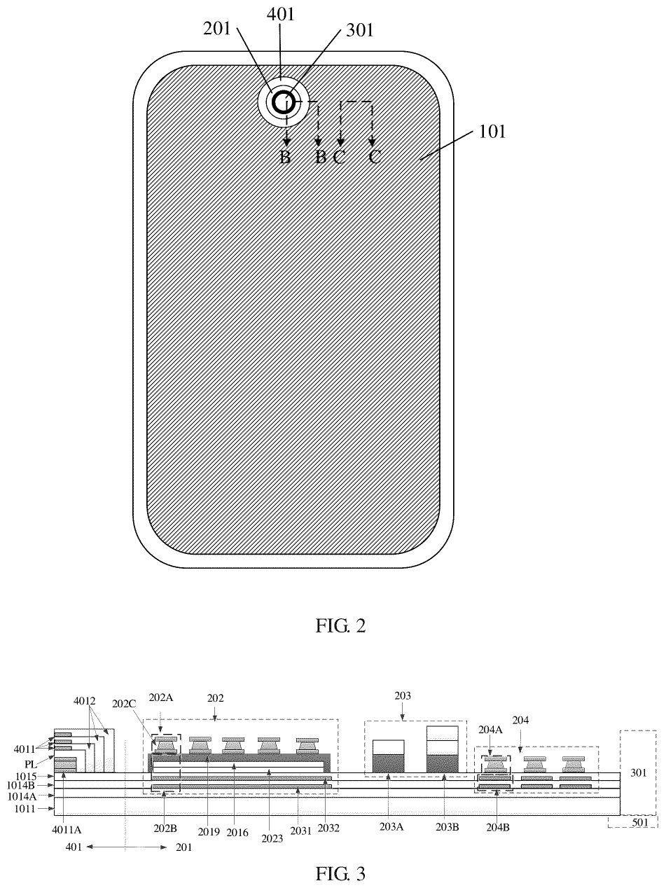

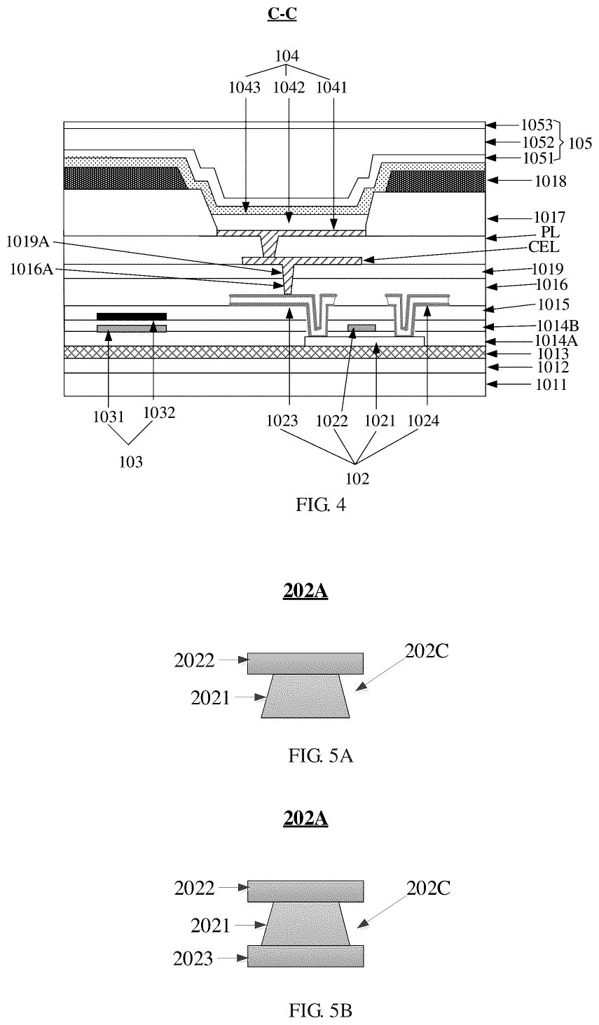

At least one embodiment of the present disclosure provides a display substrate, and FIG. 2 shows a schematic plan view of the display substrate, FIG. 3 shows a schematic cross-sectional view of the display substrate taken along the line B-B, and FIG. 4 shows a schematic cross-sectional view of the display substrate taken along the line C-C.

As shown in FIGS. 2 and 3, the display substrate has a display area 101, a barrier region 201 and an opening region 301, and includes a base substrate 1011. As shown in FIG. 1, the display area 101 and the barrier region 201 surround the opening region 301, and the barrier region 201 is located between the display area 101 and the opening region 301.

For example, as shown in FIG. 3, the barrier region 201 includes at least one barrier wall 202 (five barrier walls 202 are shown in the figure as an example) that at least partially surrounds (for example, completely surrounds) the opening region 301, and each barrier wall 202 includes a first metal layer structure 202A and a first stack structure 202B, and the first metal layer structure 202A is located on the side of the first stack structure 202A away from the base substrate 1011, at least one side surface, surrounding the opening region 301, of the first metal layer structure 202A has a first notch 202C.

For example, the side surface of the first metal layer structure 202A facing the opening region 301 has a first notch 202C, or the side surface of the first metal layer structure 202A facing the display area 101 has a first notch 202C, or the side surface of the first metal layer structure 202A facing the opening region 301 and the side surface facing the display area 101 of the first metal layer structure 202A have a first notch 202C, as shown in FIG. 3.

In the embodiment of the present disclosure, the barrier wall 202 can disconnect the functional layers formed on the whole surface of the display substrate, such as the light-emitting material layer of the light-emitting device (to be described in detail later), so that impurities, such as water and oxygen, can be effectively prevented from entering the display area 101 of the display substrate from the opening region 301 along the functional layers, such as the light-emitting material layer, so that the reliability of the display substrate can be improved.

For example, as shown in FIG. 4, the display area 101 includes a plurality of sub-pixels, and each sub-pixel includes a pixel driver circuit and a light-emitting device 104. The pixel driver circuit includes a thin film transistor 102, a storage capacitor 103, a connection electrode CEL and other structures. For example, the thin film transistor 102 includes an active layer 1021, a first source-drain electrode 1023 and a second source-drain electrode 1024, one of the first source-drain electrode 1023 and a second source-drain electrode 1024 is the source electrode and the other is the drain electrode. The storage capacitor 103 includes a first capacitor plate 1031 and a second capacitor plate 1032.

For example, the light-emitting device 104 includes a first electrode 1041, a second electrode 1043, and a light-emitting material layer 1042 between the first electrode 1041 and the second electrode 1043, and the connection electrode CEL is configured to electrically connect the first electrode 1041 and the first source-drain electrode 1023. For example, the first electrode 1041 is realized as an anode of the light-emitting device 104, and the second electrode 1043 is realized as a cathode of the light-emitting device 104. The light-emitting material layer 1042 may include an organic luminescent layer and an auxiliary luminescent layer, and the auxiliary luminescent layer includes one or more selected from a group consisting of an electron transport layer, an electron injection layer, a hole transport layer and a hole injection layer.

For example, the first metal layer structure 202A of the barrier wall 202 is arranged in the same layer as the connection electrode CEL.

In the embodiment of the present disclosure, “in a/the same layer” means that two (or more) functional layers or structural layers are in the same layer and formed of the same material in the hierarchical structure of the display substrate, that is, in the preparation process of the display substrate, the two functional layers or structural layers can be formed by the same material layer, and the required patterns and structures can be formed by the same one patterning process. Therefore, the preparation process of the display substrate can be simplified.

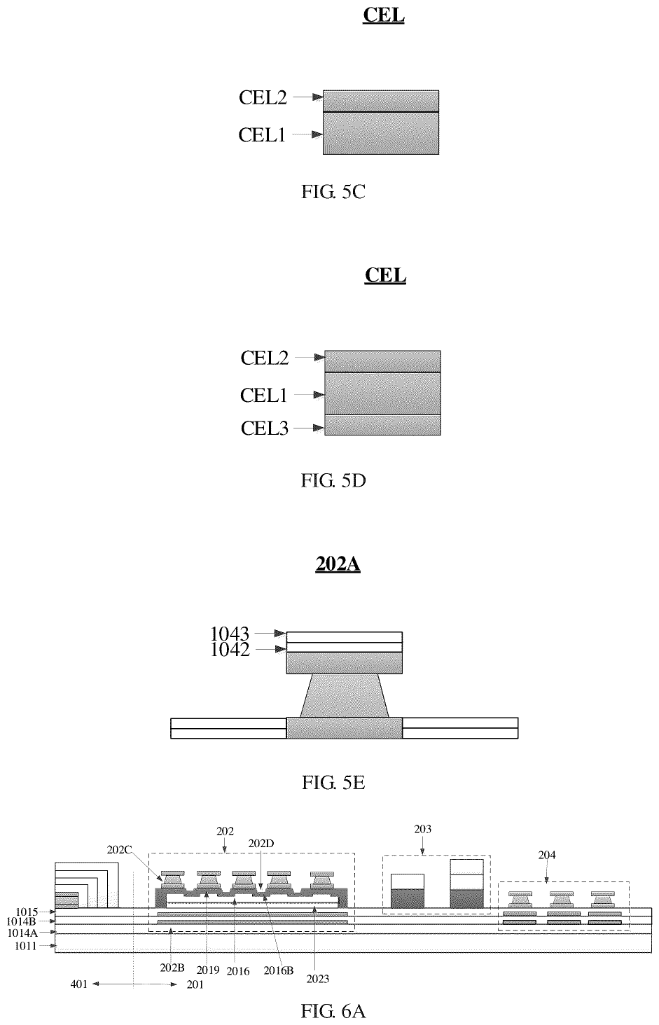

For example, in some embodiments, as shown in FIG. 5A, the first metal layer structure 202A includes a first metal sub-layer 2021 and a second metal sub-layer 2022 arranged on the side of the first metal sub-layer 2021 away from the base substrate 1011, and the first metal sub-layer 2021 is retracted inward relative to the second metal sub-layer 2022 in the direction parallel to the board surface of the base substrate 1011, that is, in the horizontal direction in the figure, to form the first notch 202C. Or, in other embodiments, as shown in FIG. 5B, the first metal layer structure 202A includes a first metal sub-layer 2021, a second metal sub-layer 2022 arranged on the side of the first metal sub-layer 2021 away from the base substrate 1011, and a third metal sub-layer 2023 arranged on the side of the first metal sub-layer 2021 near the base substrate 1011. The first metal sub-layer 2021 is retracted inward relative to the second metal sub-layer 2022 and the third metal sub-layer 2023 in the direction parallel to the board surface of the base substrate 1011 to form the first notch 202C, which is the situation shown in FIG. 3.

For example, for the first metal layer structure 202A shown in FIG. 5A, as shown in FIG. 5C, the connection electrode CEL in this case includes a first sub-layer CELL and a second sub-layer CEL2, and the first metal sub-layer 2021 and the second metal sub-layer 2022 of the first metal layer structure 202A are respectively arranged in the same layer corresponding to the first sub-layer CEL1 and the first sub-layer CEL2 one by one. For example, for the first metal layer structure 202A shown in FIG. 5B, as shown in FIG. 5D, the connection electrode CEL in this case includes a first sub-layer CEL1, a second sub-layer CEL2 and a third sub-layer CEL3, and the first metal sub-layer 2021, the second metal sub-layer 2022 and the third metal sub-layer 2023 of the first metal layer structure 202A are respectively arranged in the same layer corresponding to the first sub-layer CEL1, the second sub-layer CEL2 and the third sub-layer CEL3 one by one. For the sake of clarity and conciseness, the multilayer structure of the connection electrode CEL is not shown in FIG. 4.

For example, for the embodiments of FIGS. 5A and 5C, the double-layer metal structures of the connection electrode CEL and the first metal layer structure 202A may be titanium/aluminum, molybdenum/aluminum, titanium/copper or molybdenum/copper, etc., while for the embodiments of FIGS. 5B and 5D, the three-layer metal layer structures of the connection electrode CEL and the first metal layer structure 202A may be titanium/aluminum/titanium, molybdenum/aluminum/molybdenum, etc., the embodiment of the present disclosure does not limit the specific material for the connection electrode CEL and the first metal layer structure 202A.

For example, in some embodiments, the light-emitting material layer 1042 and the second electrode 1043 are formed on the whole surface of the display substrate, in this case, as shown in FIG. 5E, the barrier wall 202 can disconnect both the light-emitting material layer 1042 and the second electrode 1043, thereby when the light-emitting material layer 1042 and the second electrode 1043 located near the opening region 301 are polluted by impurities, such as water and oxygen, because the light-emitting material layer 1042 and the second electrode 1043 are disconnected by the barrier wall 202, these pollutants cannot extend into the light-emitting material layer 1042 and the second electrode 1043 in the display area 101 for emitting light. For example, a part of the light-emitting material layer 1042 and a part of the second electrode 1043 are also formed on the top of the barrier wall 202, but these parts are separated from other parts thereof.

For example, in some embodiments, as shown in FIG. 4, the display area 101 further includes a first planarization layer 1016 arranged on the side of the first source-drain electrode 1023 and the second source-drain electrode 1024 away from the base substrate 1011, and the first planarization layer 1016 has a first via hole 1016A, and the connection electrode CEL is disposed on the side of the first planarization layer 1016 away from the base substrate 1011, and is electrically connected to the base substrate 1011 through the first via hole 1016A. For example, as shown in FIG. 3, the first stack structure 202B of the barrier wall 202 includes a first insulation sub-layer 2016 disposed on the base substrate 1011, and the first insulation sub-layer 2016 is in the same layer as the first planarization layer 1016.

For example, in some embodiments, as shown in FIG. 4, the display area 101 may further include a first passivation layer 1019 disposed on the side of the first planarization layer 1016 away from the base substrate 1011, the first passivation layer 1019 has a second via hole 1019A communicating with the first via hole 1016A, and the connection electrode CEL is disposed on the side of the first passivation layer 1019 away from the base substrate 1011 and is electrically connected with the first source-drain electrode 1023 through the first via 1016A and the second via 1019A. For example, as shown in FIG. 3, the first stack structure 202B further includes a second insulation sub-layer 2019 disposed on the side of the first insulation sub-layer 2016A away from the base substrate 1011, and the second insulation sub-layer 2019 is in the same layer as the first passivation layer 1019.

For example, in some embodiments, as shown in FIG. 3, the at least one barrier wall 202 includes a plurality of barrier walls 202. For example, the first metal layer structures 202A of a plurality of barrier walls 202 are in the same layer and spaced apart from each other, and the first stack structures 202B of a plurality of barrier walls 202 are in the same layer and constitute an integral structure. Therefore, the plurality of barrier walls 202 can fully realize the function of disconnecting the functional layers, such as the light-emitting material layer 1042 and the second electrode 1043, and the first stack structure 202B can block up the first metal layer structure 202A, so that the height of the first metal layer structure 202A relative to the base substrate 1011 is higher.

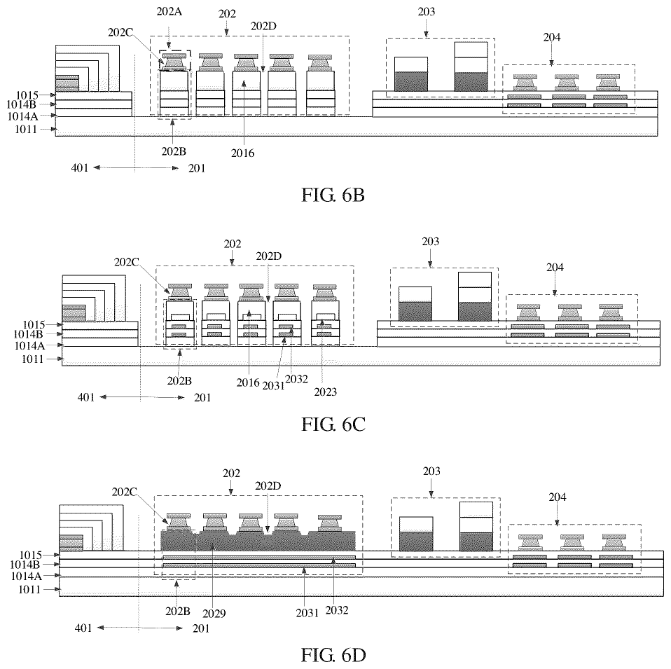

For example, in some embodiments, as shown in FIG. 6A, the integral structure formed by the first stack structures 202B of the plurality of barrier walls 202 has a barrier groove 202D between the first metal layer structures 202A of the adjacent barrier walls 202. The barrier groove 202D is more conducive to disconnecting the functional layers, such as the light-emitting material layer 1042 and the second electrode 1043 formed on the whole surface.

For example, in some embodiments, as shown in FIG. 6A, the first insulation sub-layer 2016 has a groove 2016B between the first metal layer structures 202A of the adjacent barrier walls 202, and the second insulation sub-layer 2019 is formed on the side of the first insulation sub-layer 2016 away from the base substrate 1011 with an equal thickness to form the barrier groove 202D at the position of the groove 2016B.

For example, in some embodiments, as shown in FIGS. 3 and 6A, the first stack structure 202B may further include a first metal layer 2023, the first metal layer 2023 is disposed on the side of the first insulation sub-layer 2016 near the base substrate 1011. For example, the first metal layer 2023 is in the same layer as the first source-drain electrode 1023 and the second source-drain electrode 1024.

For example, in some embodiments, as shown in FIG. 4, the thin film transistor 102 further includes a first gate electrode 1022, the first gate electrode 1022 is arranged on the side of the first source-drain electrode 1023 and the second source-drain electrode 1024 near the base substrate 1011, and the first capacitor plate 1031 of the storage capacitor 103 is in the same layer as the first gate electrode 1022, and the second capacitor plate 1032 is arranged on the side of the first capacitor plate 1031 away from the base substrate. For example, as shown in FIG. 3, the first stack structure 202B may further include a second metal layer 2032 and a third metal layer 2031 that both are arranged on the side of the first metal layer 2023 near the base substrate 1011, and the second metal layer 2032 is arranged on the side of the third metal layer 2031 away from the base substrate 1011. For example, the second metal layer 2032 is in the same layer as the second capacitor plate 1032, and the third metal layer 2031 is in the same layer as the first capacitor plate 1031.

For example, as shown in FIG. 4, the display area 101 further includes a gate insulation layer 1014B disposed between the first gate electrode 1022 and the second capacitor plate 1032, and the gate insulation layer 1014B further extends into the barrier region 201 and is disposed between the second metal layer 2032 and the third metal layer 2031, as shown in FIG. 3.

For example, as shown in FIG. 4, the display area 101 further includes an interlayer insulation layer 1015 disposed on the side of the second capacitor plate 1032 away from the base substrate 1011, and the interlayer insulation layer 1015 further extends into the barrier region 201 and is disposed on the side of the second metal layer 2032 away from the base substrate 1011, as shown in FIG. 3.

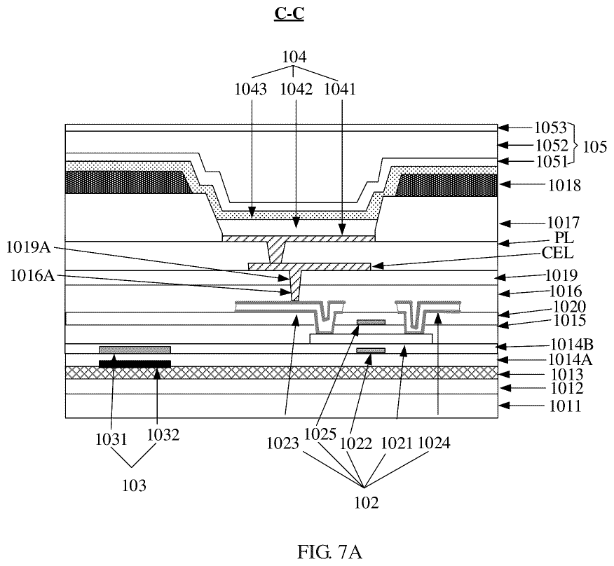

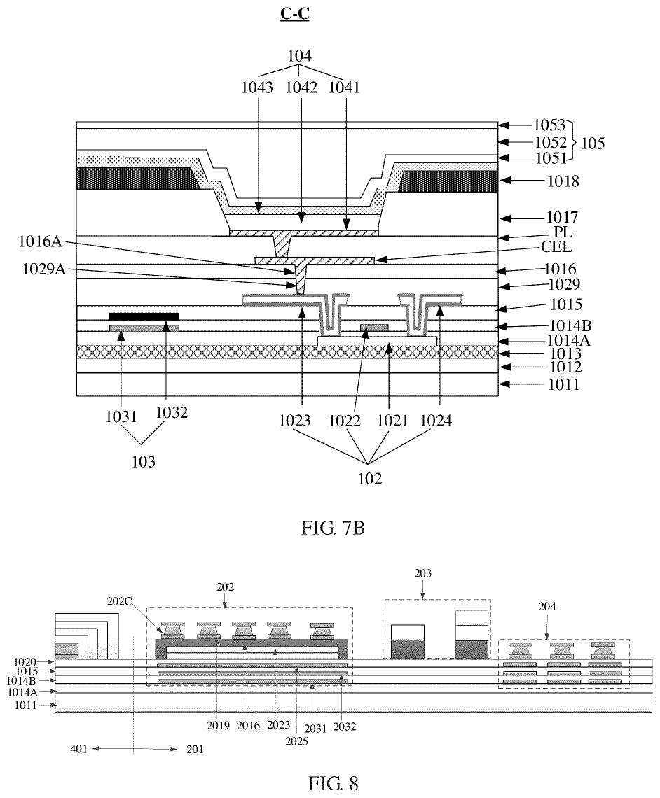

For example, in other embodiments, as shown in FIG. 7A, the thin film transistor may further include a second gate electrode 1025, that is, the thin film transistor is formed in the form of a double-gate thin film transistor. In this case, the first gate electrode 1022 and the second gate electrode 1025 are respectively located on two opposite sides of the active layer 1021, for example, the first gate electrode 1022 is located on the side of the active layer 1021 near the base substrate 1011, and the second gate electrode 1025 is located on the side of the active layer 1021 away from the base substrate 1011. For example, as shown in FIG. 7A, the second gate electrode 1025 is disposed on the side of the interlayer insulation layer 1015 away from the base substrate 1011. For example, as shown in FIG. 8, the first stack structure 202B may further include a fourth metal layer 2025 disposed between the first metal layer 2023 and the second metal layer 2032, and the fourth metal layer 2025 is disposed in the same layer as the second gate electrode 1025.

For example, as shown in FIG. 7A, the display area 101 further includes another interlayer insulation layer 1020 disposed on the side of the second gate electrode 1025 away from the base substrate 101, and the interlayer insulation layer 1020 further extends into the barrier region 201 and is disposed on the side of the fourth metal layer 2025 away from the base substrate 1011, as shown in FIG. 8.

Therefore, the first stack structure 202A includes a stack structure with a plurality of stack insulation layers and metal layers, and has a high thickness, so the height of the first metal layer structure 202A disposed on the first stack structure 202B is relatively high relative to the base substrate. For example, in the preparation process of the display substrate, the first notch 202C of the first metal layer structure 202A can be formed with the same etching process and the same etching solution as for the first electrode 1041. During the etching, a photoresist pattern with a certain thickness is usually formed on the display substrate, for example, it is required that the photoresist pattern covers a plurality of conductive layers 4011 and insulation layers 4012 (described in detail later) in the circuit region 401, in this case, because a distance from the first metal layer structure 202A to the base substrate is far, the problem that the first notch 202C of the first metal layer structure 202A cannot be accurately formed due to too thick photoresist and incomplete etching can be avoided.

For example, in some embodiments, as shown in FIG. 6B, the first metal layer structures 202A of the plurality of barrier walls 202 are in the same layer and spaced apart from each other, and the first stack structures 202B of the plurality of barrier walls 202 are also in the same layer and spaced apart from each other.

For example, in the embodiment of FIG. 6B, the first stack structure 202B includes a plurality of sub-layers arranged in the same layer as the gate insulation layer 1014A, the gate insulation layer 1014B, the interlayer insulation layer 1015 and the first planarization layer 1016.

For example, in other embodiments, as shown in FIG. 6C, the first stack structure 202B includes a plurality of sub-layers arranged in the same layer as the gate insulation layer 1014A, the first gate electrode 1021, the gate insulation layer 1014B, the second capacitor plate 1032, the interlayer insulation layer 1015, the first source-drain electrode 1023 and the first planarization layer 1016.

For example, in some embodiments, as shown in FIGS. 7B and 6D, the display area further includes a second passivation layer 1029 disposed on the side of the first source-drain electrode 1023 and the second source-drain electrode 1024 away from the base substrate 1011, and the second passivation layer 1029 has a third via hole 1029A, and the connection electrode CEL is disposed on the side of the second passivation layer 1029 away from the base substrate 1011 and connected with the first passivation layer 1029A through the third via hole 1029A. For example, the first planarization layer 1016 is disposed on the side of the second passivation layer 1029 away from the base substrate 1011, and the first via hole 1016A and the third via hole 1029A in the first planarization layer 1016 communicate with each other, and the connection electrode CEL is electrically connected with the first source-drain electrode 1023 through the first via hole 1016A and the third via hole 1029A.

For example, as shown in FIG. 6D, the first stack structure 202B includes a third insulation sub-layer 2029 disposed on the base substrate 1011, and the third insulation sub-layer 2029 is disposed in the same layer as the second passivation layer 1029.

For example, as shown in FIG. 6D, the barrier region includes a plurality of barrier walls 202, the first metal layer structures 202A of the plurality of barrier walls 202 are in the same layer and spaced apart from each other, and the first stack structures 202B of the plurality of barrier walls 202 are arranged in the same layer and constitute an integral structure. For example, the third insulation sub-layer 2029 in the integral structure has a barrier groove 202D between the first metal layer structures 202A of adjacent barrier walls 202. For example, in other embodiments, the first stack structure 202B of the plurality of barrier walls 202 may also be in the same layer and spaced apart from each other, thus having a structure similar to that shown in FIG. 6B or 6C.

For example, in some embodiments, as shown in FIG. 4, the display substrate may further include structures such as a pixel definition layer 1017, a spacer 1018, etc. The pixel definition layer 1017 is disposed on the side of the first planarization layer 1016 away from the thin film transistor 102, and includes a plurality of sub-pixel openings for defining the light-emitting region of the light-emitting device 104. The spacer 1018 is disposed on the side of the pixel definition layer 1017 away from the planarization layer 1016 to define the encapsulation space.

For example, in some embodiments, as shown in FIG. 3, the barrier region 201 may further include at least one interception wall 203, such as a plurality of interception walls 203 (two interception walls are shown in the figure as an example), for example, the plurality of interception walls 203 at least partially surround (e.g., completely surround) the opening region 301, to intercept organic materials formed in the display area 101 in the preparation process of the display substrate so as to prevent these organic materials from flow out. For example, the interception wall 203 includes a plurality of insulation sub-layers, these insulation sub-layers are respectively arranged in the same layer as at least two elements selected from a group consisting of the planarization layer 1016, the pixel definition layer 1017 and the spacer 1018.

For example, as shown in FIG. 3, the interception wall 203A includes two insulation sub-layers, the two insulation sub-layers may be in one-to-one correspondence to two elements selected from a group consisting of the planarization layer 1016, the pixel definition layer 1017 and the spacer 1018, respectively, and be arranged in the same layer as the corresponding layer respectively. For example, the interception wall 203B includes three insulation sub-layers, the three insulation sub-layers are arranged in one-to-one correspondence to the planarization layer 1016, the pixel definition layer 1017 and the spacer 1018, respectively, and are arranged in the same layer as the corresponding layers, respectively. Therefore, in the preparation process, these functional layers arranged in the same layer can be formed by the same one material layer and the same one patterning process, so as to simplify the preparation process of the display substrate.

For example, as shown in FIG. 4, the display substrate further includes an encapsulation layer 105, and the encapsulation layer 105 includes a first inorganic encapsulation layer 1051, a first organic encapsulation layer 1052, and a second inorganic encapsulation layer 1053 that are sequentially stacked. For example, the first inorganic encapsulation layer 1051 and the second inorganic encapsulation layer 1053 may be formed on the whole surface of the display substrate, and the first organic encapsulation layer 1052 can be terminated at the interception wall 203 because of the interception effect of the interception wall 203.

For example, in some embodiments, as shown in FIG. 3, the barrier region 201 may further include at least one crack-blocking dam 204 arranged on the side of the interception wall 203 near the opening region 301, for example, including a plurality of crack-blocking dams 204, and the plurality of crack-blocking dams 204 at least partially surround (for example, completely surround) the opening region 301, for example, to avoid the formation of cracks and block the cracks to extend to the display area 100 when the opening region 301 is formed by stamping or cutting in the preparation process of the display substrate.

For example, as shown in FIG. 3, the crack-blocking dam 204 includes a second metal layer structure 204A and a second stack structure 204B, the second metal layer structure 204A and the first metal layer structure 202A are arranged in the same layer and have basically the same structure. The second stack structure 204B includes, for example, a plurality of metal sub-layers, the plurality of metal sub-layers are respectively arranged in the same layer as the first gate electrode 1022 and the second capacitor plate 1032, or, in other embodiments, as shown in FIG. 8, the plurality of metal sub-layers are respectively arranged in the same layer as at least two elements selected from a group consisting of the first gate electrode 1022, the second capacitor plate 1032 and the second gate electrode 1025.

For example, in some embodiments, as shown in FIGS. 2 and 3, the display substrate further includes a circuit region 401 which is disposed between the display area 101 and the barrier region 201 and at least partially surrounds the display area 101, and the circuit region 401 includes a plurality of conductive layers 4011 and a plurality of insulation layers 4012 respectively located between adjacent conductive layers 4011. For example, the circuit region 401 further includes a conductive layer 4011A, the conductive layer 4011A is arranged in the same layer as the connection electrode CEL and the first metal layer structure 202A, and the sidewall of the conductive layer 4011A has no notch but has a flush sidewall structure.

For example, the plurality of conductive layers 4011 may be made of a transparent metal oxide, such as ITO and IZO, or a metal material, such as copper, aluminum and molybdenum or an alloy material, and the plurality of insulation layers 4012 may be made of an organic insulation material, such as polyimide and resin. For example, the circuit pattern formed by the plurality of conductive layers 4011 may be a circuit pattern for providing a display signal, such as a scanning signal or a data signal, for the display area 101; or a circuit pattern for providing a driving signal for the image sensor/infrared sensor 501 formed in the opening region 301. The embodiment of the present disclosure does not limit the specific form of the plurality of conductive layers 4011.

For example, the whole structure of the plurality of conductive layers 4011 and the plurality of insulation layers 4012 has a relatively high thickness. When the first metal layer structure 202A of the barrier wall 202 is formed by the etching process, the whole structure of the plurality of conductive layers 4011 and the plurality of insulation layers 4012 need to be covered and protected by the photoresist. In the embodiments of the present disclosure, by arranging the first stack structure 202A below the first metal layer structure 202A, the first metal layer structure 202A can also be in a higher position, so that the photoresist located on the first metal layer structure 202A cannot be too thick to be accurately etched, thereby facilitating the formation of the first notch of the subsequent first metal layer structure 202A. For example, in some embodiments, as shown in FIG. 3, the display substrate may further include an image sensor and/or an infrared sensor 501, the image sensor and/or the infrared sensor 501 are combined with the base substrate 1011 and are on the non-display side of the display substrate, and the orthographic projection of the image sensor and/or the infrared sensor 501 on the base substrate 1011 at least partially overlaps with the opening region 301. In this way, the image sensor and/or the infrared sensor 501 can realize various functions, such as photographing, face recognition, infrared sensing, etc., through the opening region 301.

In the embodiment of the present disclosure, the display substrate may be a flexible display substrate, in this case, the base substrate 1011 may be a flexible substrate, such as a polyimide (PI) substrate, or the base substrate 1011 may be a rigid substrate, and in this case, the base substrate 1011 may be a rigid substrate, such as a glass substrate or a quartz substrate.

For example, a barrier layer 1012 and a buffer layer 1013 may further be disposed on the base substrate 1011. For example, the barrier layer 1012 and the buffer layer 1013 may be formed on the whole surface of the base substrate 1011. For the sake of clarity and conciseness, the barrier layer 1012 and the buffer layer 1013 are not shown in FIGS. 3, 6A and 8. For example, the barrier layer 1012 may be made of an inorganic insulation material, such as silicon oxide, silicon nitride, or silicon oxynitride, and can prevent impurities, such as water and oxygen, from infiltrating into the functional structures, such as the thin film transistor 102, from the base substrate 1011. For example, the buffer layer 1013 may be made of an inorganic insulation material such as silicon oxide, silicon nitride, or silicon oxynitride. The buffer layer 1013 can provide a flat surface to facilitate the arrangement of other functional layers of the display substrate. The barrier layer 1012 and the buffer layer 1013 can jointly protect other functional structures on the base substrate 1011.

For example, the materials of the first gate electrode 1022, the second gate electrode 1025, the first capacitor plate 1031, and the second capacitor plate 1032 may include a metal or alloy, such as aluminum, titanium, copper, cobalt, and may be formed into a single-layer metal structure or a multi-layer metal structure, such as titanium/aluminum/titanium, molybdenum/aluminum/molybdenum, titanium/copper/titanium or molybdenum/copper/molybdenum. The active layer 1021 may be made of polysilicon and metal oxide, and another gate insulation layer 1014A is provided on the active layer 1021. The gate insulation layer 1014A, the gate insulation layer 1014B, and the interlayer insulation layer 1015 may be made of an inorganic insulation material, such as silicon oxide, silicon nitride or silicon oxynitride.

For example, a second planarization layer PL is further provided on the connection electrode CEL, a third via hole is provided in the second planarization layer PL, and the first electrode 1041 is electrically connected with the connection electrode CEL through the third via hole. For example, the materials of the first planarization layer 1016, the second planarization layer PL, the pixel definition layer 1017, the spacer 1018, and the first organic encapsulation layer 1052 may be an organic insulation material, such as polyimide, epoxy resin. The first inorganic encapsulation layer 1051 and the second inorganic encapsulation layer 1053 may be made of an inorganic insulation material, such as silicon oxide, silicon nitride, silicon oxynitride.

For example, the material of the first electrode 1041 includes a metal oxide, such as ITO, IZO, or a metal, such as Ag, Al, Mo, or the alloys thereof. The material of the organic light-emitting layer in the light-emitting material layer 1042 may be selected as required to emit a given color light (such as red light, blue light, or green light). The material of the second electrode 1043 may include a metal, such as Mg, Ca, Li or Al or the alloys thereof, or a metal oxide, such as IZO, ZTO, or an organic material with a conductive property, such as PEDOT/PSS (poly 3,4-ethylenedioxythiophene/polystyrene sulfonate).

The embodiments of the present disclosure do not limit the materials of each functional layers, and the materials of each functional layer are not limited to the above examples.

At least one embodiment of the present disclosure also provides a display device, and the display device includes the display substrate provided by the embodiments of the present disclosure. For example, the display device may be a mobile phone, a tablet computer, a television, a display, a notebook computer, a digital photo frame, a navigator and other products or components with display functions, and the embodiments of the present disclosure impose no limitation to this.

At least one embodiment of the present disclosure also provides a method for preparing a display substrate, and the method for preparing the display substrate comprises: forming a display area, a barrier region, and an opening region, in which the display area and the barrier region surround the opening region, and the barrier region is between the display area and the opening region. Forming the barrier region comprises: forming at least one barrier wall at least partially surrounding the opening region, in which each of the at least one barrier wall comprises a first metal layer structure and a first stack structure, and the first metal layer structure is formed on a side of the first stack structure away from the base substrate, and at least a side surface, surrounding the opening region, of the first metal layer structure, has a first notch; forming the display area comprises: forming a plurality of sub-pixels, each of the plurality of sub-pixels comprises a pixel driver circuit and a light-emitting device, in which the pixel driver circuit comprises a thin film transistor and a connection electrode, the thin film transistor comprises a first source-drain electrode and a second source-drain electrode, and the light-emitting device comprises a first electrode, a second electrode, and a light-emitting material layer between the first electrode and the second electrode, and the connection electrode is formed to electrically connect the first electrode and the first source-drain electrode. For example, the first metal layer structure and the connection electrode are formed in a same layer.

For example, in some embodiments, the first metal layer structure includes a first metal sub-layer and a second metal sub-layer formed on the side of the first metal sub-layer away from the base substrate, and the first metal sub-layer is formed to be retracted inward relative to the second metal sub-layer in the direction parallel to the board surface of the base substrate to form a first notch, referring to FIG. 5A; Or, the first metal layer structure includes a first metal sub-layer, a second metal sub-layer formed on the side of the first metal sub-layer away from the base substrate, and a third metal sub-layer formed on the side of the first metal sub-layer near the base substrate, and in the direction parallel to the board surface of the base substrate, the first metal sub-layer is formed to be retracted inward relative to the second metal sub-layer and the third metal sub-layer to form a first notch, referring to FIG. 5B.

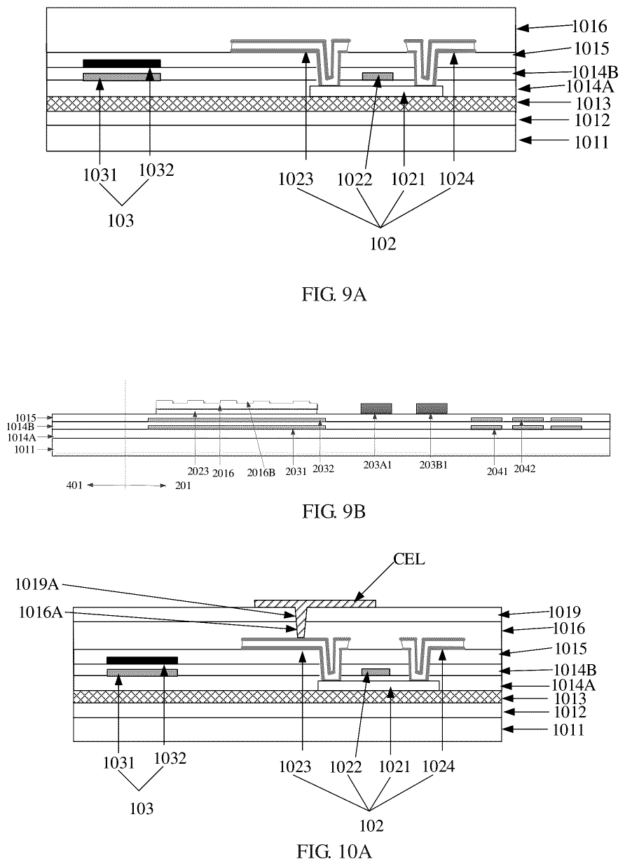

Next, with reference to FIGS. 9A-11B, the method for preparing the display substrate provided by at least one embodiment of the present disclosure is exemplarily described. For example, the method for preparing the display substrate shown in FIGS. 3 and 4 is introduced as an example.

As shown in FIG. 9A, first, a base substrate 1011 is provided. For example, in the case that the display substrate is a flexible display substrate, the provided base substrate 1011 may be a flexible substrate, such as a polyimide (PI) substrate, and in the case that the display substrate is a rigid substrate, the base substrate 1011 may be a rigid substrate, such as a glass substrate or a quartz substrate.

As shown in FIG. 9A, first, the functional layers for the display area 101, the barrier region 201, and the circuit region 401 are formed on the base substrate 1011, and a position is reserved for the opening region 301, so that the opening region 301 can be formed by stamping or cutting after the functional layers of the display area 101, the barrier region 201 and the circuit region 401 are formed.

For example, the barrier layer 1012 and the buffer layer 1013 may be sequentially formed on the base substrate 1011 by a process, such as deposition process. For example, the barrier layer 1012 and the buffer layer 1013 may be formed on the whole surface of the base substrate 1011. For example, the barrier layer 1012 may be made of an inorganic insulation material, such as silicon oxide, silicon nitride, silicon oxynitride, and the buffer layer 1013 may also be made of an inorganic insulation material, such as silicon oxide, silicon nitride, silicon oxynitride.

For example, after the barrier layer 1012 and the buffer layer 1013 are formed, as shown in FIG. 9A, structures, such as the thin film transistor 102, the storage capacitor 103 and the first planarization layer 1016, are formed in the display area 101, and as shown in FIG. 9B, the first stack structure 202B of the barrier wall 202 and the second stack structure 204B of the crack-blocking dam 204 are formed in the barrier region 201. These structures can be formed by a patterning process. For example, one patterning process includes steps, such as photoresist formation, exposure, development, and etching.

For example, as shown in FIGS. 9A and 9B, an active layer 1021 is formed on the base substrate 1011 by a patterning process; a gate insulation layer 1014A is formed on the active layer 1021 by a deposition process or the like; the first gate electrode 1022, the first capacitor plate 1031, the third metal layer 2031 in the first stack structure, and the metal sub-layer 2041 in the second stack structure are simultaneously formed on the gate insulation layer 1014A by a patterning process; then, a gate insulation layer 1014B is formed by, for example, a deposition process; then, the second capacitor plate 1032, the second metal layer 2032 of the first stack structure 202B, and the metal sub-layer 2042 of the second stack structure 204B are simultaneously formed by a patterning process; then, an interlayer insulation layer 1015 is formed by a deposition process, and a via hole exposing the active layer 1021 is formed in the gate insulation layers 1014A/1014B and the interlayer insulation layer 1015.

For example, the materials of the first gate electrode 1022, the first capacitor plate 1031, the third metal layer 2031 of the first stack structure 202B and the metal sub-layer 2041 of the second stack structure 204B include a metal, such as aluminum, titanium and cobalt or an alloy material. During the preparation process, a gate material layer is formed by a sputtering or evaporation process, etc., and then the gate material layer is patterned to form the patterned gate electrode 211, the first capacitor plate 1031, the second metal layer 2032 of the first stack structure 202B and the metal sub-layer 2041 of the second stack structure 204B. Other structures formed in the same layer are formed in a similar way, so they are not described in detail.

For example, the active layer 1021 may be made of polysilicon or a metal oxide, etc., the gate insulation layers 1014A/1014B may be made of an inorganic insulation material, such as silicon oxide, silicon nitride, silicon oxynitride, the second capacitor plate 1032, the second metal layer 2032 of the first stack structure 202B and the metal sub-layer 2042 of the second stack structure 204B may be made of a metal, such as aluminum, titanium, cobalt, or an alloy material, and the interlayer insulation layer 1015 may be made of an inorganic insulation material, such as silicon oxide, silicon nitride, silicon oxynitride. The embodiments of the present disclosure do not limit the materials of each functional layer, and the materials of each functional layer are not limited to the above examples.

As shown in FIG. 9A, after the via holes in the gate insulation layers 1014A/1014B and the interlayer insulation layer 1015 are formed, the first source-drain electrode 1023, the second source-drain electrode 1024 and the first metal layer 2023 of the first stack structure 202B of the barrier wall 202 are formed.

For example, the first source-drain electrode 1023 and the second source-drain electrode 1024 may be formed as a multi-layer metal structure, for example, a three-layer metal structure. For example, in an example, a titanium material layer, an aluminum material layer and a titanium material layer may be sequentially formed by sputtering or evaporation process, etc., and then the three material layers are patterned by a same patterning process, thereby forming a titanium/aluminum/titanium three-layer metal structure that constitutes the first source-drain electrode 1023 and the second source-drain electrode 1024. For the sake of clarity and brief introduction, the three-layer metal structure is not shown in some drawings.

For example, as shown in FIGS. 9A and 9B, a first planarization layer 1016 and a first insulation sub-layer 2016 of the first stack structure for forming the barrier wall are formed on the side of the first source-drain electrode 1023 and the second source-drain electrode 1024 away from the base substrate 1011 by, for example, a patterning process, and a groove 2016B is formed in the first insulation sub-layer 2016. For example, while the first planarization layer 1016 is formed, the insulation sub-layer 203A1 of the interception wall 203A and the insulation sub-layer 203B1 of the interception wall 203B are also formed simultaneously.

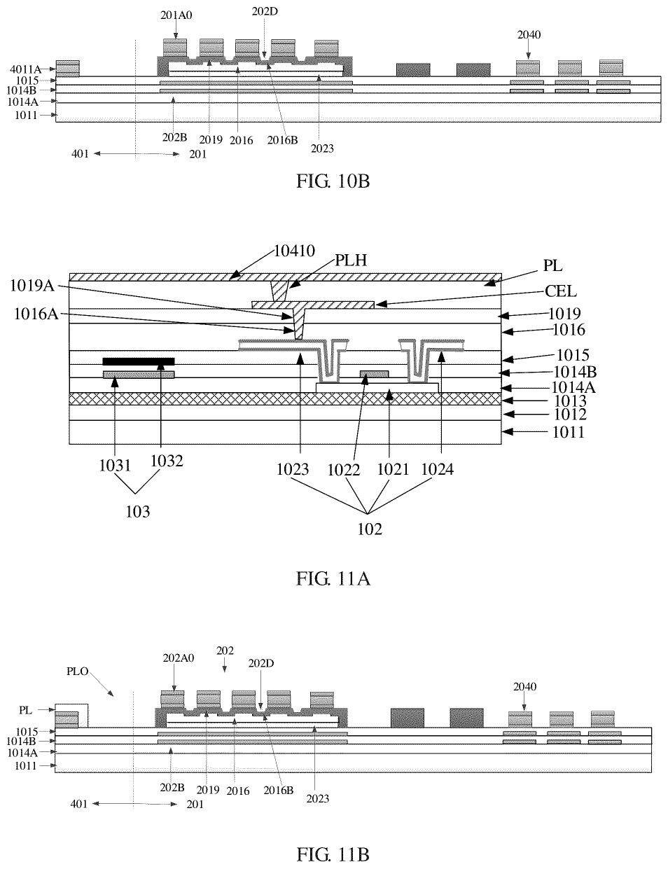

As shown in FIGS. 10A and 10B, a first passivation layer 1019 and a second insulation sub-layer 2019 are formed in the same layer on the first planarization layer 1016 and the first insulation sub-layer 2016. For example, a first passivation layer 1019 is formed on the first planarization layer 1016, and a second via hole 1019A and a first via hole 1016A that expose the first source-drain electrode 1023 and communicate with each other are respectively formed in the first passivation layer 1019 and the first planarization layer 1016. In this case, the second insulation sub-layer 2019 is formed on the first insulation sub-layer 2016B of the first stack structure 202B of the barrier wall with an equal thickness, for example, and a barrier groove 202D is formed at the position of the groove 2016B.

For example, in some embodiments, the display substrate has a plurality of barrier walls 202, the first stack structures 202B of the barrier walls 202 are formed in the same layer and form as an integral structure, and the integral structure is formed with the barrier groove 202D between adjacent first metal layer structures.

For example, in other embodiments, corresponding to the structures shown in FIGS. 6D and 7B, a second passivation layer 1029 is formed on the side of the first source-drain electrode 1023 and the second source-drain electrode 1024 away from the base substrate 1011, the second passivation layer 1029 has a third via hole 1029A, a first planarization layer 1016 is formed on the side of the second passivation layer 1029 away from the base substrate 1011, and the first planarization layer 1016 has a first via hole 1016A which communicates with the third via hole 1029A. The connection electrode CEL is formed on the side of the second passivation layer 1029 away from the base substrate 1011, more specifically on the side of the first planarization layer 1016 away from the base substrate 1011, and is electrically connected with the first source-drain electrode 1023 through the third via hole 1029A and the first via hole 1016A. For example, while forming the second passivation layer 1029, the third insulation sub-layer 2029 of the first stack structure 202B is formed in the same layer simultaneously, and the barrier groove 202D is formed in the third insulation sub-layer 2029, as shown in FIG. 6D.

For example, as shown in FIGS. 10A and 10B, for example, a connection electrode material layer is formed on the first passivation layer 1019 by a sputtering or a deposition process etc., and then the connection electrode material layer is patterned to form a connection electrode CEL and an first metal layer initial structure 201A0, for example, a second metal layer initial structure 2040 of the crack-blocking dam 204 and a conductive layer 4011A in the circuit region 401 are also formed simultaneously. In this case, each of the first metal layer initial structure 201A0, the second metal layer initial structure 2040, and the conductive layer 4011A located in the circuit region 401 has a structure with a flush sidewall, respectively.

For example, the first metal layer initial structures 201A0 of a plurality of barrier walls 202 are formed in the same layer and at intervals, so that the first metal layer structures 202A of the finally formed plurality of barrier walls 202 are formed in the same layer and spaced apart from each other. For example, the second metal layer initial structures 2040 of the plurality of crack-blocking dams 204 are also formed in the same layer and spaced apart from each other.

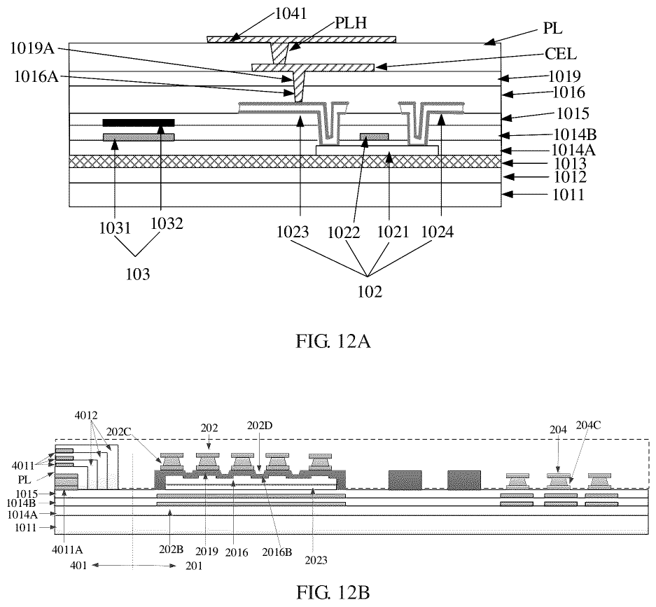

For example, as shown in FIGS. 11A and 11B, a second planarization layer PL the is formed on the side of the connection electrode CEL and the first metal layer initial structure 201A0 away from the base substrate 1011, and the second planarization layer PL includes a third via hole PLH exposing the connection electrode CEL and an opening PLO exposing the first metal layer initial structure 201A0. A first electrode material layer 10410 is formed on the side of the second planarization layer PL away from the base substrate 1011, and the first electrode material layer 10410 and the first metal layer initial structure 202A0 are etched with the same etching solution to form a first electrode 1041 and a first notch 202C, for example, a second notch 204C in the second metal layer structure is also formed at the same time, and the first electrode 1041 is electrically connected to the connection electrode CEL through the third via hole PLH, as shown in FIG. 12A and FIG. 12B.

For example, the etching solution used above has an etching effect on the intermediate layer of the first metal layer structure 202A and the intermediate layer of the second metal layer structure 204A or the etching rate of the intermediate layers is higher than that of other layers, so that the etching process can form the notches in the first metal layer structure 202A and the second metal layer structure 204A.

For example, in some embodiments, a circuit region 401 is also formed on the display substrate, for example, the circuit region 401 is formed between the display area 101 and the barrier region 201 and at least partially surrounds the display area 101, and the circuit region 401 includes a plurality of conductive layers 4011 and a plurality of insulation layers 4012 located between adjacent conductive layers 4011; for example, after the connection electrode CEL and the first metal layer initial structure 202A0 are formed, the plurality of conductive layers 4011 and the plurality of insulation layers 4012 between adjacent conductive layers are formed, and then the first electrode material layer 10410 and the first metal layer initial structure 202A0 are etched with the same solution.

For example, the whole structure of the plurality of conductive layers 4011 and the plurality of insulation layers 4012 has a relatively high thickness, when the first metal layer structure 202A of the barrier wall 202 is formed by an etching process, the whole structure of the plurality of conductive layers 4011 and the plurality of insulation layers 4012 need to be covered and protected by the photoresist. For example, the coating range of the photoresist is shown by the dashed frame in FIG. 12B. In the embodiments of the present disclosure, by arranging the first stack structure 202A below the first metal layer structure 202A, the first metal layer structure 202A can also be located in a higher position, so that the problem that the photoresist located on the first metal layer structure 202A cannot be accurately etched due to the too large thickness of the photoresist can be avoided, thereby facilitating the formation of the first notch 202C of the subsequently formed first metal layer structure 202A.

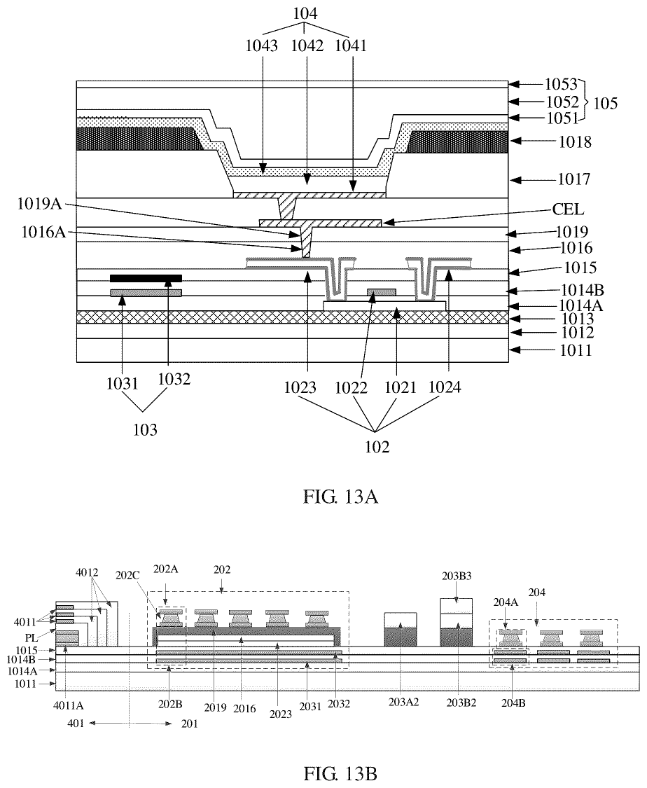

For example, after the first electrode 1041 is formed, the pixel definition layer 1017, the spacer 1018, the light-emitting material layer 1042, the second electrode 1043, and the encapsulation layer 105, etc., are formed in sequence, and other insulation sub-layers of the interception wall 203 are formed at the same time, as shown in FIGS. 13A and 13B.

For example, the pixel definition layer 1017, the insulation sub-layer 203A2 of the interception wall 203A and the insulation sub-layer 203B2 of the interception wall 203B are formed in the same layer by a patterning process. The pixel definition layer 1017 has a sub-pixel opening exposing the first electrode 1041, which is convenient for subsequently forming the structures, such as the light-emitting material layer 1042 and the second electrode 1043 of the light-emitting device. For example, the material of the pixel definition layer 1017 may include an organic insulation material, such as polyimide, and epoxy resin.

For example, the spacer 1018 and the insulation sub-layer 203B3 of the interception wall 203B are formed in the same layer by a patterning process. The material of the spacer 1018 includes an organic insulation material, such as polyimide, and epoxy resin.

For example, the light-emitting material layer 1042 may be formed in the sub-pixel opening of the pixel definition layer 1017 by inkjet printing or evaporation process, etc., and then the second electrode 1043 may be formed by a sputtering process, etc. For example, the light-emitting material layer 1042 and the second electrode 1043 are formed on the whole surface of the display substrate and are disconnected at the barrier wall 202 and the crack-blocking dam 204.

For example, the material of the light-emitting material layer 1042 may be an organic luminescent material that can emit a given color light (such as red light, blue light or green light, etc.) as required. The material of the second electrode 1043 may include metals, such as Mg, Ca, Li, and Al, or their alloys, or a metal oxide, such as IZO and ZTO, or an organic material with a conductive property, such as PEDOT/PSS (poly 3,4-ethylenedioxythiophene/polystyrene sulfonate).

For example, after the light-emitting device 104 is formed, the encapsulation layer 105 is formed. For example, the encapsulation layer 105 includes a first inorganic encapsulation layer 1051, a first organic encapsulation layer 1052, and a second inorganic encapsulation layer 1053. For example, the first inorganic encapsulation layer 1051 and the second inorganic encapsulation layer 1053 are formed by a deposition process, etc. The first organic encapsulation layer 1052 is formed by inkjet printing. For example, because of the interception effect of the interception wall 203, the first organic encapsulation layer 1052 can be terminated at the interception wall 203.

For example, the first inorganic encapsulation layer 1051 and the second inorganic encapsulation layer 1053 may be formed of an inorganic material, such as silicon nitride, silicon oxide, and silicon oxynitride, and the first organic encapsulation layer 1052 may be formed of an organic material, such as polyimide (PI), and epoxy resin. In this way, the first inorganic encapsulation layer 1051, the first organic encapsulation layer 1052, and the second inorganic encapsulation layer 1053 are formed into a composite encapsulation layer, thereby having a better encapsulation effect.

For example, after the display area 101 is formed, the opening region 301 may be formed by laser cutting or mechanical stamping. The opening region 301 penetrates through the base substrate 1011, and structures, such as the image sensor and the infrared sensor, can be installed at the opening region 301, and the opening region 301 is connected in signal with structures, such as a central processing unit. For example, the structures, such as the image sensor or the infrared sensor, can be arranged on the side of the base substrate 1011 away from the light-emitting device (i.e., the non-display side of the display substrate), and various functions, such as photographing, face recognition, and infrared sensing, can be realized through the opening region 301.

For example, after the opening region 301 is formed, a polarizer, a cover plate, and other structures may be formed on the display substrate, which is not limited by the embodiment of the present disclosure.

The following several points should be noted:
(1) The accompanying drawings involve only the structure(s) in connection with the embodiment(s) of the present disclosure, and other structure(s) can refer to common design(s).
(2) For the purpose of clarity only, in the accompanying drawings for illustrating the embodiment(s) of the present disclosure, the thickness and size of a layer or a region may be enlarged or narrowed, that is, the drawings are not drawn in a real scale. It is to be understood that, in the case in which a component, such as a layer, a film, a region, and a base substrate is referred to be “on” or “under/below” another component, the component may be directly on or under/below the another component or there may be an intermediate component.
(3) Without conflicting with each other, embodiments of the present disclosure and the features in the embodiments may be mutually combined to obtain new embodiments.

The above descriptions are only specific embodiments of the present disclosure, but the scope of the present disclosure is not limited thereto, the scope of the present disclosure should be defined by the claims.

1. A display substrate, having a display area, a barrier region, and an opening region, and comprising a base substrate, wherein the display area and the barrier region surround the opening region, and the barrier region is between the display area and the opening region,
the barrier region comprises at least one barrier wall at least partially surrounding the opening region, and each of the at least one barrier wall comprises a first metal layer structure and a first stack structure, the first metal layer structure is on a side of the first stack structure away from the base substrate, and at least a side surface, surrounding the opening region, of the first metal layer structure has a first notch;
the display area comprises a plurality of sub-pixels, each of the plurality of sub-pixels comprises a pixel driver circuit and a light-emitting device, the pixel driver circuit comprises a thin film transistor and a connection electrode, and the thin film transistor comprises a first source-drain electrode and a second source-drain electrode, and the light-emitting device comprises a first electrode, a second electrode, and a light-emitting material layer between the first electrode and the second electrode, and the connection electrode is configured to electrically connect the first electrode and the first source-drain electrode; and
the first metal layer structure is in a same layer as the connection electrode.

2. The display substrate according to claim 1, wherein the first metal layer structure comprises a first metal sub-layer and a second metal sub-layer on a side of the first metal sub-layer away from the base substrate, and the first metal sub-layer is retracted inward relative to the second metal sub-layer in a direction parallel to a board surface of the base substrate to form the first notch; or,
the first metal layer structure comprises a first metal sub-layer, a second metal sub-layer on a side of the first metal sub-layer away from the base substrate, and a third metal sub-layer on a side of the first metal sub-layer near the base substrate, and the first metal sub-layer is retracted inward relative to the second metal sub-layer and the third metal sub-layer in the direction parallel to the board surface of the base substrate to form the first notch.

3. The display substrate according to claim 1, wherein the display area further comprises a first planarization layer on a side of the first source-drain electrode and the second source-drain electrode away from the base substrate, the first planarization layer has a first via hole, and the connection electrode is on a side of the first planarization layer away from the base substrate and is electrically connected with the first source-drain electrode through the first via hole,
the first stack structure comprises a first insulation sub-layer on the base substrate, and
the first insulation sub-layer and the first planarization layer are in a same layer.

4. The display substrate according to claim 3, wherein the at least one barrier wall comprises a plurality of barrier walls;
the first metal layers of the plurality of barrier walls are in a same layer and spaced apart from each other, and the first stack structures of the plurality of barrier walls are in a same layer and spaced apart from each other; or,
the first metal layers of the plurality of barrier walls are in a same layer and spaced apart from each other, and the first stack structures of the plurality of barrier walls are in the same layer and constitute an integral structure; and the integral structure has a barrier groove between the first metal layer structures of adjacent ones of the plurality of barrier walls.

5. (canceled)

6. The display substrate according to claim 4, wherein the display area further comprises a first passivation layer on a side of the first planarization layer away from the base substrate, the first passivation layer has a second via hole communicated with the first via hole, the connection electrode is on a side of the first passivation layer away from the base substrate, and is electrically connected with the first source-drain electrode through the first via hole and the second via hole,
the first stack structure further comprises a second insulation sub-layer arranged on a side of the first insulation sub-layer away from the base substrate, and
the second insulation sub-layer and the first passivation layer are in a same layer.

7. The display substrate according to claim 6, wherein the first insulation sub-layer has a groove between the first metal layer structures of adjacent ones of the plurality of barrier walls, and the second insulation sub-layer is formed on a side of the first insulation sub-layer away from the base substrate with an equal thickness to form the barrier groove at the position of the groove.

8. The display substrate according to claim 1, wherein the display area further comprises a second passivation layer arranged on a side of the first source-drain electrode and the second source-drain electrode away from the base substrate, the second passivation layer has a third via hole, and the connection electrode is on a side of the second passivation layer away from the base substrate and is electrically connected with the first source-drain electrode through the third via hole,
the first stack structure comprises a third insulation sub-layer on the base substrate, and
the third insulation sub-layer and the second passivation layer are arranged in the same layer.

9. The display substrate according to claim 8, wherein the at least one barrier wall comprises a plurality of barrier walls;
the first metal layers of the plurality of barrier walls are in a same layer and spaced apart from each other, and the first stack structures of the plurality of barrier walls are in a same layer and spaced apart from each other; or,
the first metal layers of the plurality of barrier walls are in a same layer and spaced apart from each other, and the first stack structures of the plurality of barrier walls are in the same layer and constitute an integral structure.

10. The display substrate according to claim 9, wherein the third insulation sub-layer in the integral structure has a barrier groove between the first metal layer structures of adjacent ones of the plurality of barrier walls.

11. The display substrate according to claim 3, wherein the first stack structure further comprises a first metal layer, the first metal layer is on a side of the first insulation sub-layer near the base substrate, and
the first metal layer is in a same layer as the first source-drain electrode and the second source-drain electrode.

12. The display substrate according to claim 8, wherein the pixel driver circuit further comprises a storage capacitor, the thin film transistor further comprises a first gate electrode, and the first gate electrode is on a side of the first source-drain electrode and the second source-drain electrode near the base substrate,
the storage capacitor comprises a first capacitor plate and a second capacitor plate, the first capacitor plate is in a same layer as the first gate electrode, and the second capacitor plate is on a side of the first capacitor plate away from the base substrate,
the first stack structure further comprises a second metal layer and a third metal layer, the second metal layer is on a side of the third metal layer away from the base substrate,
the second metal layer is in a same layer as the second capacitor plate, and the third metal layer is in the same layer as the first capacitor plate.

13. The display substrate according to claim 12, wherein the display area further comprises a gate insulation layer between the first gate electrode and the second capacitor plate, and the gate insulation layer further extends into the barrier region and is between the second metal layer and the third metal layer,
wherein the display area further comprises an interlayer insulation layer on a side of the second capacitor plate away from the base substrate, and the interlayer insulation layer further extends into the barrier region and is on a side of the second metal layer away from the base substrate.

14. (canceled)

15. The display substrate according to claim 13, wherein the thin film transistor further comprises a second gate electrode, and the second gate electrode is on a side of the interlayer insulation layer away from the base substrate,
the first stack structure further comprises a fourth metal layer, and the fourth metal layer is in a same layer as the second gate electrode.

16. The display substrate according to claim 1, further comprising: a circuit region which is between the display area and the barrier region and at least partially surrounds the display area, wherein
the circuit region comprises a plurality of conductive layers and a plurality of insulation layers between adjacent ones of the plurality of conductive layers.

17. A display device, comprising the display substrate according to claim 1.

18. A method for preparing a display substrate, comprising:
forming a display area, a barrier region, and an opening region, wherein the display area and the barrier region surround the opening region, and the barrier region is between the display area and the opening region;
forming the barrier region comprises: forming at least one barrier wall at least partially surrounding the opening region, wherein each of the at least one barrier walls comprises a first metal layer structure and a first stack structure, and the first metal layer structure is formed on a side of the first stack structure away from the base substrate, and at least a side surface, surrounding the opening region, of the first metal layer structure has a first notch;
forming the display area comprises: forming a plurality of sub-pixels, each of the plurality of sub-pixels comprises a pixel driver circuit and a light-emitting device, wherein the pixel driver circuit comprises a thin film transistor and a connection electrode, and the thin film transistor comprises a first source-drain electrode and a second source-drain electrode, and the light-emitting device comprises a first electrode, a second electrode and a light-emitting material layer between the first electrode and the second electrode, and the connection electrode is formed to electrically connect the first electrode and the first source-drain electrode; and
the first metal layer structure and the connection electrode are formed in a same layer.

19. The preparation method according to claim 18, wherein the first metal layer structure comprises a first metal sub-layer and a second metal sub-layer on a side of the first metal sub-layer away from the base substrate, and the first metal sub-layer is retracted inward relative to the second metal sub-layer in a direction parallel to a board surface of the base substrate to form the first notch; or,
the first metal layer structure comprises a first metal sub-layer, a second metal sub-layer on a side of the first metal sub-layer away from the base substrate, and a third metal sub-layer on a side of the first metal sub-layer near the base substrate, and the first metal sub-layer is retracted inward relative to the second metal sub-layer and the third metal sub-layer in the direction parallel to the board surface of the base substrate to form the first notch;
forming the display area further comprises: forming a first planarization layer on a side of the first source-drain electrode and the second source-drain electrode away from the base substrate, wherein the first planarization layer has a first via hole, and the connection electrode is formed on a side of the first planarization layer away from the base substrate and is electrically connected with the first source-drain electrode through the first via hole,
the first stack structure comprises a first insulation sub-layer formed on the base substrate, and
the first insulation sub-layer and the first planarization layer are formed in a same layer.

20. The preparation method according to claim 18, wherein the first metal layer structure comprises a first metal sub-layer and a second metal sub-layer formed on a side of the first metal sub-layer away from the base substrate, and the first metal sub-layer is formed to be retracted inward relative to the second metal sub-layer in a direction parallel to a board surface of the base substrate to form the first notch; or,
the first metal layer structure comprises a first metal sub-layer, a second metal sub-layer formed on a side of the first metal sub-layer away from the base substrate, and a third metal sub-layer formed on a side of the first metal sub-layer near the base substrate, and the first metal sub-layer is formed to be retracted inward relative to the second metal sub-layer and the third metal sub-layer in the direction parallel to the board surface of the base substrate to form the first notch;
forming the display area further comprises: forming a second passivation layer on a side of the first source-drain electrode and the second source-drain electrode away from the base substrate, wherein the second passivation layer has a third via hole, and the connection electrode is formed on a side of the second passivation layer away from the base substrate and is electrically connected with the first source-drain electrode through the third via hole,
the first stack structure comprises a third insulation sub-layer formed on the base substrate, and
the third insulation sub-layer is formed in a same layer as the second passivation layer.

21. The preparation method according to claim 20, wherein forming the first metal layer structure and the connection electrode comprises:
forming a connection electrode material layer, and pattern the connection electrode material layer to form the connection electrode and a first metal layer initial structure;
forming a second planarization layer on a side of the connection electrode and the first metal layer initial structure away from the base substrate, wherein the second planarization layer comprises a third via hole exposing the connection electrode and an opening exposing the first metal layer initial structure;
forming a first electrode material layer on a side of the second planarization layer away from the base substrate,
etching the first electrode material layer and the initial structure of the first electrode material layer with a same etching solution to form the first electrode and the first notch, and the first electrode is electrically connected with the connection electrode through the third via hole.

22. The preparation method according to claim 21, further comprising: forming a circuit region which is between the display area and the barrier region and at least partially surrounding the display area,
the circuit region comprises a plurality of conductive layers, and a plurality of insulation layers between adjacent ones of the plurality of conductive layers, wherein,
after the connection electrode and the first metal layer initial structure are formed, the plurality of conductive layers and the plurality of insulation layers between the adjacent ones of the plurality of conductive layers are formed, and then the first electrode material layer and the first metal layer initial structure are etched by a same etching solution.
